(19) United States
(12) Patent Application Publication
(10) Pub. No.: US 2025/0194195 A1
(43) Pub. Date: Jun. 12, 2025

(54) MULTILAYERED STRUCTURE, MANUFACTURING METHOD THEREOF, AND SEMICONDUCTOR DEVICE

(71) Applicant: Japan Display Inc., Tokyo (JP)

(72) Inventors: Hayata AOKI, Tokyo (JP); Masumi NISHIMURA, Tokyo (JP)

(73) Assignee: Japan Display Inc., Tokyo (JP)

(21) Appl. No.: 19/058,400

(22) Filed: Feb. 20, 2025

Related U.S. Application Data
(63) Continuation of application No. PCT/JP2023/021906, filed on Jun. 13, 2023.

(30) Foreign Application Priority Data
Sep. 1, 2022 (JP) 2022-139266

(51) Int. Cl. H10D 62/85; H01L 21/02; H10D 30/47; H10D 62/10

(52) U.S. Cl. CPC H10D 62/8503; H01L 21/02428; H01L 21/02516; H01L 21/0254; H10D 62/115; H10D 30/475

(57) ABSTRACT

A multilayered structure includes an amorphous substrate having an insulating surface; an orientation layer having a pattern on the amorphous substrate having the insulating surface; a semiconductor layer containing gallium nitride having a pattern arranged on the orientation layer; and a side protection portion containing gallium nitride arranged on a side surface of the orientation layer, wherein the semiconductor layer and the side protection portion are separated at the side surface of the orientation layer.

### CROSS-REFERENCE TO RELATED APPLICATIONS

This application is a Continuation of International Patent Application No. PCT/JP2023/021906, filed on Jun. 13, 2023, which claims the benefit of priority to Japanese Patent Application No. 2022-139266, filed on Sep. 1, 2022, the entire contents of which are incorporated herein by reference.

### FIELD

An embodiment of the present invention relates to a multilayered structure containing a semiconductor layer having gallium nitride, a method for manufacturing the multilayered structure, and a semiconductor device using the multilayered structure.

### BACKGROUND

In recent years, a semiconductor device using a semiconductor layer (hereinafter referred to as “gallium nitride-based semiconductor layer”) containing gallium nitride (GaN) has been developed. For example, a transistor element such as a HEMT (High Electron Mobility Transistor) and a light-emitting element such as an LED (Light-emitting Diode) are known as the semiconductor device using the gallium nitride-based semiconductor layer. In particular, demand for a light-emitting device using the light-emitting diode (LED) for each pixel is high, and a technique for forming a highly crystalline gallium nitride-based semiconductor layer on a substrate other than a silicon substrate has been rapidly developed. For example, patent literature 1 discloses a technique in which a buffer layer is formed on an insulating substrate such as a sapphire substrate or a quartz glass substrate, an insulating pattern is formed on the buffer layer, and the gallium nitride-based semiconductor layer is formed on the buffer layer and the insulating pattern (See Japanese laid-open patent publication No. 2018-168029).

### SUMMARY

A multilayered structure according to an embodiment of the present disclosure includes an amorphous substrate having an insulating surface; an orientation layer having a pattern on the amorphous substrate having the insulating surface; a semiconductor layer containing gallium nitride having a pattern arranged on the orientation layer; and a side protection portion containing gallium nitride arranged on a side surface of the orientation layer, wherein the semiconductor layer and the side protection portion are separated at the side surface of the orientation layer.

A multilayered structure according to an embodiment of the present disclosure includes an amorphous substrate having an insulating surface; an orientation layer having a pattern on the amorphous substrate having the insulating surface; a semiconductor layer containing gallium nitride having a pattern arranged on a top surface of the orientation layer; and a side protection portion containing gallium nitride arranged on a side surface of the orientation layer, wherein the orientation layer contains an exposed portion not covered by the semiconductor layer and the side protection portion, and the exposed portion is arranged between the semiconductor layer and the side protection portion.

A manufacturing method of a multilayered structure according to an embodiment of the present disclosure includes forming an orientation layer having a pattern on an amorphous substrate having an insulating surface; forming a semiconductor film containing gallium nitride to cover the orientation layer; and forming a semiconductor layer containing gallium nitride having a pattern on a top surface of the orientation layer by etching the semiconductor film, as well as forming a side protection portion containing gallium nitride arranged on a side surface of the orientation layer, wherein the semiconductor layer and the side protection portion are separated from each other.

A manufacturing method of a multilayered structure according to an embodiment of the present disclosure includes forming an orientation layer having a pattern on an amorphous substrate having an insulating surface; depositing a semiconductor film containing gallium nitride to cover the orientation layer; and etching the semiconductor film to expose a portion of the orientation layer from the semiconductor film at a side surface of the orientation layer.

### BRIEF DESCRIPTION OF DRAWINGS

FIG. 1 is an end view showing a method for manufacturing a multilayered structure according to a first embodiment of the present invention.

FIG. 2 is an end view showing a method for manufacturing a multilayered structure according to the first embodiment of the present invention.

FIG. 3 is an end view showing a method for manufacturing a multilayered structure according to the first embodiment of the present invention.

FIG. 4 is an end view showing a method for manufacturing a multilayered structure according to the first embodiment of the present invention.

FIG. 5 is an end view showing a method for manufacturing a multilayered structure according to the first embodiment of the present invention.

FIG. 6 is an end view showing a method for manufacturing a multilayered structure according to the first embodiment of the present invention.

FIG. 7 is an end view showing a semiconductor device having a multilayered structure according to the first embodiment of the present invention.

FIG. 8 is a plan view showing a light emitting device using a semiconductor device containing a multilayered structure according to the first embodiment of the present invention.

FIG. 9 is an end view showing a method for manufacturing a multilayered structure according to the first embodiment of the present invention.

FIG. 10 is an end view showing a method for manufacturing a multilayered structure according to the first embodiment of the present invention.

FIG. 11 is an end view showing a semiconductor device having a multilayered structure according to a second embodiment of the present invention.

### DESCRIPTION OF EMBODIMENTS

As in the above-described prior art, generally, a semiconductor layer containing gallium nitride is formed by epitaxial growth at a temperature exceeding 1000° C. using a sapphire substrate or a quartz glass substrate having a heat resistance of 1000° C. or higher. However, considering applications to a light-emitting display device, the use of expensive sapphire substrate or quartz glass substrate is problematic in that it hinders the increase in the area of a display screen. In addition, in the processing at a temperature exceeding 1000° C., it takes time to raise the temperature at the start of the processing and to lower the temperature at the end of the processing, and the throughput decreases.

An embodiment of the present invention uses a semiconductor layer containing gallium nitride with high crystallinity on an inexpensive amorphous substrate to form a multilayered structure.

Also, an embodiment of the present invention is to form a multilayered structure with a semiconductor layer containing gallium nitride with high crystallinity at a high throughput.

Hereinafter, embodiments of the present invention will be described with reference to the drawings and the like. However, the present invention can be implemented in various forms without departing from the gist thereof. The present invention is not to be construed as being limited to the description of the embodiments exemplified below. In the drawings, the widths, thicknesses, shapes, and the like of the respective portions may be schematically represented in comparison with actual embodiments for clarity of explanation. However, the drawings are merely examples, and do not limit the interpretation of the present invention.

In describing an embodiment of the present invention, a direction from a substrate toward a semiconductor layer is referred to as “on”, and a reverse direction thereof is referred to as “under”. However, the expression “on” or “under” merely describes the vertical relationship of each element. In addition, the expression “on” or “under” includes not only the case where a third element is interposed between the first element and the second element, but also the case where it is not interposed. Furthermore, the terms “on” or “under” include not only the case where the elements overlap in a plan view, but also the case where they do not overlap.

In describing the embodiments of the present invention, elements having the same functions as those described above may be denoted by the same reference signs or the same reference signs plus letters or other symbols, and descriptions thereof may be omitted. In addition, in the case where a part of an element needs to be described separately, a symbol such as a letter may be attached to a symbol indicating the element to distinguish the element. However, when it is not necessary to distinguish each part of the element, the description will be made using only the reference signs indicating the element.

In describing embodiments of the present invention, expressions such as “α includes A, B, or C,” “α includes any of A, B, and C,” and “α includes one selected from a group consisting of A, B, and C” do not exclude the case where α includes a plurality of combinations of A to C unless otherwise specified. Furthermore, these expressions do not exclude the case where α includes other elements.

### First Embodiment

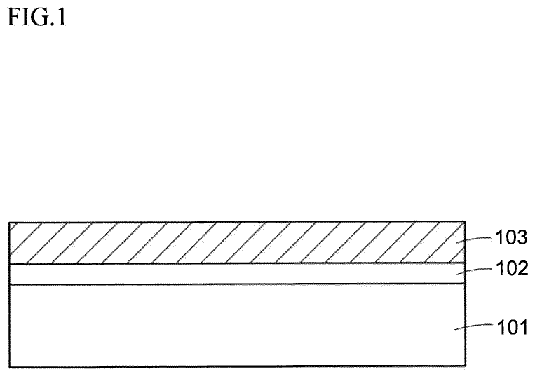

FIG. 1 to FIG. 6 is end views showing methods for manufacturing a multilayered structure having a semiconductor layer containing gallium nitride according to a first embodiment. In particular, FIG. 1 to FIG. 6 show examples of forming a semiconductor layer containing gallium nitride having a pattern on an amorphous substrate. In addition, FIG. 1 to FIG. 6 show an example in which a single semiconductor is formed, but in practice, a plurality of semiconductors is formed on the substrate.

First, as shown in FIG. 1, a base film 102 is formed on an amorphous substrate 101. For example, a glass substrate can be used as the amorphous substrate 101. The glass substrate preferably has a low content of alkaline components, a low thermal expansion coefficient, a high strain point, and a high surface flatness. For example, the content of the alkali metal (such as sodium) is 0.1% or less, the thermal expansion coefficient is lower than 50×10⁻⁷/° C., and the strain point is preferably 600° C. or higher. As will be described later, in the present embodiment, since the gallium nitride-based semiconductor film is formed by a sputtering method, a glass substrate having lower heat resistance than that of a sapphire substrate or quartz substrate can be used. Such a glass substrate is cheaper than the sapphire substrate and the quartz substrate, and is also suitable for increasing the area of the mother glass. However, the amorphous substrate 101 of the present embodiment is not limited to the glass substrate, and may be a resin substrate such as a polyimide substrate, an acryl substrate, a siloxane substrate, or a fluororesin substrate.

The base film 102 serves as a protective film that prevents an impurity from entering from the amorphous substrate 101. For example, the base film 102 is composed of one or more films selected from a silicon nitride film, a silicon oxide film, an aluminum nitride film, and an aluminum oxide film. The base film 102 can also cover the top or surface of the amorphous substrate 101 as an insulating film since it has a function not only as a protective film but also as a film with insulating properties.

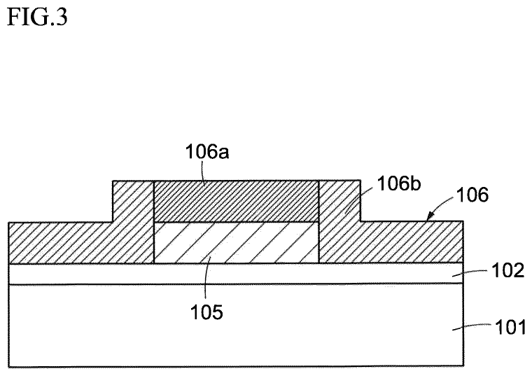

An orientation film 103 is formed on the base film 102. The orientation film 103 has the function of improving the orientation of the crystal of a semiconductor film 106 containing gallium nitride when forming the semiconductor film 106 containing gallium nitride (see FIG. 3), which will be described later.

The orientation film 103 may be conductive or insulating, but preferably has crystallinity oriented along a specific axis (for example, the c-axis). The orientation film 103 is preferably a crystal having rotational symmetry. For example, the crystal surface preferably has six-fold rotational symmetry. In addition, the orientation film 103 preferably has a hexagonal close-packed structure, a face-centered cubic structure, or a structure equivalent thereto. In this case, the structure equivalent to the hexagonal close-packed structure or the face-centered cubic structure includes a crystal structure in which the c-axis does not form 90 degrees with respect to the a-axis and the b-axis. The orientation film 103 having the hexagonal close-packed structure or the structure equivalent thereto is preferably oriented in the (001) direction, that is, the c-axis direction, with respect to the amorphous substrate 101. The orientation film 103 having the face-centered cubic structure or the structure equivalent thereto is preferably oriented in the (111) direction with respect to the amorphous substrate 101.

A surface condition of the orientation film 103 affects the crystallinity of the semiconductor film 106 containing gallium nitride, which will be described later, so it is desirable that the surface of the orientation film 103 be flat. For example, the surface of the orientation film 103 should have an arithmetic mean roughness (Ra) of less than 2.3 nm.

The orientation film 103 described above is, for example, a conductive orientation film 103. For example, conductive orientation films such as titanium (Ti), titanium nitride (TiNₓ), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), strontium iron oxide (SrFeO) and the like can be used. In particular, titanium, graphene, and zinc oxide are preferably used as the conductive orientation film 103. In the present embodiment, a titanium layer is used as the conductive orientation film 103.

The orientation film 103 described above is, for example, an insulating orientation film 103. For example, insulating orientation films such as aluminum nitride (AlN), aluminum oxide (Al₂O₃), lithium niobate (LiNbO), BiLaTiO, SrFeO, BiFeO, BaFeO, ZnFeO, PMnN-PZT, biological apatite (BAp), or the like can be used. In particular, aluminum nitride or aluminum oxide is preferably used as the insulating orientation film. In the present embodiment, the aluminum nitride layer is preferably used as the insulating orientation film 103.

In the present embodiment, the orientation film 103 may be a conductive orientation film or an insulating orientation film. In the case where there is no need to distinguish between the conductive orientation film and the insulating orientation film, the layer is expressed as the orientation film 103.

For example, a thickness of the orientation film 103 is 50 nm or more (preferably, 50 nm or more and 100 nm or less). The orientation film 103 may be formed by any method. For example, the orientation film 103 can be formed by the sputtering method, the CVD method, the vacuum vapor deposition method, the electron beam evaporation method, or other methods.

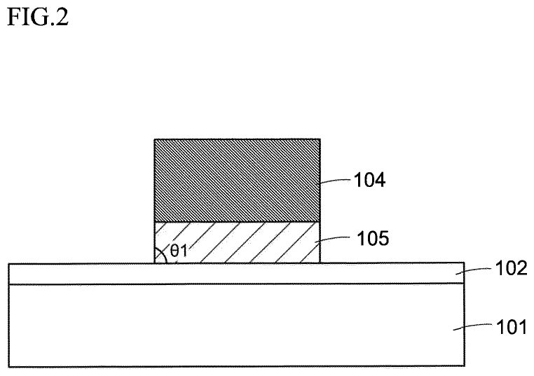

Next, as shown in FIG. 2, an orientation layer 105 having a pattern is formed by etching the orientation film 103 with a resist mask 104. The orientation layer 105 has a gradient (“taper”) where the angle between the bottom surface and the side surface is θ₁. In the present embodiment, the taper angle θ₁ of the orientation layer 105 can be equal to or greater than 60° and less than or equal to 90° since a dry etching method is used to etch the orientation film 103.

When a wet etching method is used to etch the orientation layer 103, the taper angle θ₁ tends to be small, and depending on the conditions, the taper angle θ₁ is less than 60°. For example, if the taper angle θ₁ of the orientation layer 105 is less than 60°, the area of the taper of the orientation layer 105 is larger than when the angle θ₁ is between 60° and 90°. The semiconductor film 106 containing gallium nitride formed on the taper of the orientation layer 105 tends to have lower crystallinity than the semiconductor film 106 containing gallium nitride formed on the top surface of the orientation layer 105. Therefore, this larger area causes the semiconductor film 106 containing gallium nitride with lower crystallinity to occupy a wider area in the semiconductor film 106 containing gallium nitride.

Furthermore, when the semiconductor film 106 containing gallium nitride with low crystallinity is formed on the taper of the orientation layer 105, the semiconductor film 106 containing gallium nitride with low crystallinity may inhibit crystal growth of the semiconductor film 106 containing gallium nitride deposited on the orientation layer 105. Therefore, in the present embodiment, in order to prevent such crystal growth inhibition, the area of the taper of the orientation layer 105 is suppressed, and in order to suppress the area, a dry etching method is employed so that the taper angle θ₁ of the orientation layer 105 is equal to or greater than 60° and less than or equal to 90°.

Next, as shown in FIG. 3, a semiconductor film 106 containing gallium nitride is formed to cover the orientation layer 105. In the present embodiment, the semiconductor film 106 containing gallium nitride is deposited by sputtering as the semiconductor film. Specifically, for example, the semiconductor film 106 containing gallium nitride is formed by the sputtering method in a state where the amorphous substrate 101 having an insulating surface (here, the amorphous substrate 101 in which the base film 102 is arranged) is heated to 25° C. to 600° C., preferably 25° C. to 400° C. In other words, the semiconductor film 106 containing gallium nitride is formed at a temperature equal to or lower than the strain point of the amorphous substrate 101. Although gallium nitride is usually formed by a MOCVD method (Metal Organic Chemical Vapor Deposition method), the MOCVD method is not appropriate in view of the heat resistance of the amorphous substrate 101 because the process temperature is high. However, in the present embodiment, the sputtering method can be used to form the semiconductor film 106 containing gallium nitride on the inexpensive amorphous substrate 101.

For example, the semiconductor film 106 containing gallium nitride is formed by performing the sputtering using a sintered body of gallium nitride as a sputtering target and argon (Ar) or a mixed gas of argon (Ar) and nitrogen (N₂) as a sputtering gas. For example, a two-pole sputtering method, a magnetron sputtering method, a dual magnetron sputtering method, an opposing target sputtering method, an ion beam sputtering method, or an inductively coupled plasma (ICP) sputtering method can be applied as the sputtering method.

The conductivity type of the semiconductor film 106 containing gallium nitride may be substantially intrinsic or may have n-type conductivity or p-type conductivity. The gallium nitride layer having n-type conductivity may not contain a dopant for performing valence electron control or may be doped with silicon (Si) or germanium (Ge) as an n-type dopant. The gallium nitride layer having p-type conductivity may be doped with one element selected from magnesium (Mg), zinc (Zn), cadmium (Cd), and beryllium (Be) as a p-type dopant. In the case where the n-type dopant is added to the semiconductor film 106 containing gallium nitride, the carrier concentration is preferably 1×10¹⁸/cm³ or more. In the case where the p-type dopant is added to the semiconductor film 106 containing gallium nitride, the carrier concentration is preferably 5×10¹⁶/cm³ or more. Furthermore, in the case where the semiconductor film 106 containing gallium nitride is substantially intrinsic, zinc (Zn) may be contained as a dopant.

In addition, the semiconductor film 106 may contain one or more elements selected from indium (In), aluminum (Al), and arsenic (As). A bandgap of the semiconductor film 106 containing gallium nitride can be adjusted by these elements.

As described above, in the present embodiment, the semiconductor film 106 containing gallium nitride is formed on the amorphous substrate 101 on which the orientation layer 105 is formed. The crystallinity of the semiconductor film 106 formed on the orientation layer 105 is affected by the orientation axis of the orientation layer 105. For example, in the case where the orientation layer 105 has crystallinity of rotational symmetry or c-axis oriented crystallinity, the semiconductor film 106 containing gallium nitride also has crystallinity of c-axis orientation or (111) orientation. The crystallinity of the semiconductor film 106 containing gallium nitride is preferably monocrystalline, but may be polycrystalline, microcrystalline, or nanocrystalline. The crystal structure of the semiconductor film 106 containing gallium nitride may have a wurtzite structure. The orientation of the semiconductor film 106 is preferably the c-axis orientation or (111) orientation. The semiconductor film 106 may contain an amorphous structure near the interface in contact with the orientation layer 105, but preferably has crystallinity in bulk.

The thickness of the semiconductor film 106 containing gallium nitride is not limited, and may be appropriately set according to the structure of the device. The semiconductor film 106 may have a single-layer structure, or may be a multilayered structure including a plurality of layers having different conductivity types and/or compositions.

As shown in FIG. 3, the semiconductor film 106 containing gallium nitride formed on the orientation layer 105 includes a first portion 106a, which reflects the crystallinity of the orientation layer 105, and a second portion 106b, which is less crystalline than the first portion 106a. The first portion 106a is the portion located above the orientation layer 105. The second portion 106b includes the portion located above the base film 102. In FIG. 3, an example is shown where the angle θ₁ between the bottom and side surface of the orientation layer 105 is 90°, but when the angle θ₁ is less than 90°, for example, 80°, the second portion 106b also includes the portion located above the side surface (tapered portion) of the orientation layer 105, as described above. In the orientation layer 105, the case where the angle between the bottom and side surfaces is 90° is also included in the taper angle θ₁ for convenience.

The first portion 106a has little inhibition of crystal growth by the second portion 106b because the taper angle θ₁ of the orientation layer 105 is equal to or greater than 60° and equal to or less than 90° and the area of the taper of the orientation layer 105 is suppressed, as described above.

The first portion 106a, which reflects the crystallinity of the orientation layer 105, and the second portion 106b, which is less crystalline than the first portion 106a, can be observed with a transmission electron microscope (TEM: Transmission Electron Microscope) to confirm the difference in crystallinity.

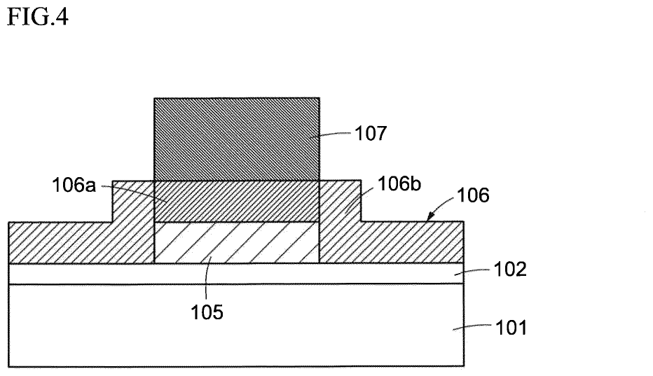

Next, as shown in FIG. 4, a resist mask 107 is formed to superimpose on the first portion 106a of the semiconductor film 106 containing a gallium nitride layer. In other words, the resist mask 107 is arranged to pattern the first portion 106a of the semiconductor film 106 containing gallium nitride, which is located above the top surface of the orientation layer 105. In the present embodiment, the side surface of the first portion 106a and the side surface of the resist mask 107 are shown to coincide, but the width of the resist mask 107 may be narrower or wider than the width of the first portion 106a, and not limited to this example.

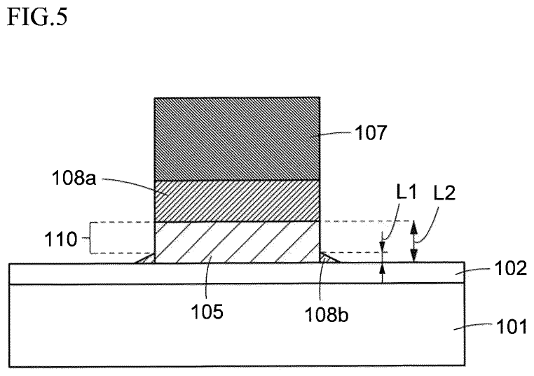

Next, as shown in FIG. 5, etching is performed on the semiconductor film 106 containing gallium nitride using a resist mask 107 to form a semiconductor layer 108a containing gallium nitride having a pattern and a side protection portion 108b containing gallium nitride. The semiconductor layer 108a is formed on the top surface of the orientation layer 105, and the side protection portion 108b is formed on the side surface of the orientation layer 105. In other words, the first portion 106a with high crystallinity of the semiconductor film 106 containing gallium nitride is used for the semiconductor layer 108a, and the second portion 106b with lower crystallinity than the first portion 106a is used for the side protection portion 108b. In the present embodiment, a dry etching method using halogen gas is used to etch the semiconductor film 106 containing gallium nitride.

Formation of the side protection portion 108b is performed successively with the formation of the semiconductor layer 108a. In detail, the semiconductor film 106 is etched and the semiconductor layer 108a is formed under the resist mask 107. Upon further etching of the semiconductor film 106, the side surface of the orientation layer 105 is partially exposed from the semiconductor film 106. Here, the portion of the side surface of the orientation layer 105 exposed from the semiconductor film 106 by this etching is referred to as the exposed portion 110. The etching of the semiconductor film 106 described above is performed until the exposed portion 110 separates the semiconductor layer 108a from the side protection portion 108b, and the side protection portion 108b is formed.

The side protection portion 108b formed as described above is provided to partially cover the side surface of the orientation layer 105, and the exposed portion 110 is located on the side surface of the orientation layer 105 that is not covered by the side protection portion 108b. In this case, the exposed portion 110 is located between the semiconductor layer 108a and the side protection portion 108b on the side surface of the orientation layer 105. Furthermore, since the side protection portion 108b is provided so that it is in contact with the base film 102, the side surface of the orientation layer 105 and the edge of the orientation layer 105 that is in contact with the base film 102 can be protected.

The film thickness L1 of the side protection portion 108b may be thinner than the film thickness L2 of the orientation layer 105 and less than half of the film thickness L2 of the orientation layer 105. Here, the film thickness L1 of the side protection portion 108b is the length of the portion in contact with the side of the orientation layer 105.

The side protection portion 108b is formed by etching the semiconductor film 106, and thus contains gallium nitride of the same composition as the gallium nitride contained in the semiconductor layer 108a, which is formed by etching the semiconductor film 106. Also, the semiconductor layer 108a and the side protection portion 108b contain gallium nitride of the same composition since the side protection portion 108b corresponds to a part of the second portion 106b of the semiconductor film 106, as described above. The crystallinity of the side protection portion 108b is also similar to the crystallinity of the second portion 106b of the semiconductor film 106 and is therefore lower than the crystallinity of the semiconductor layer 108a corresponding to the first portion 106a of the semiconductor film 106. Due to the low crystallinity of the side protection portion 108b, the conductivity of the side protection portion 108b is low, in other words, it is highly insulating. Therefore, the side protection portion 108b contains gallium nitride of the same composition as the semiconductor layer 108a, but does not conduct with the semiconductor layer 108a, even when located on the side surface of the orientation layer 105.

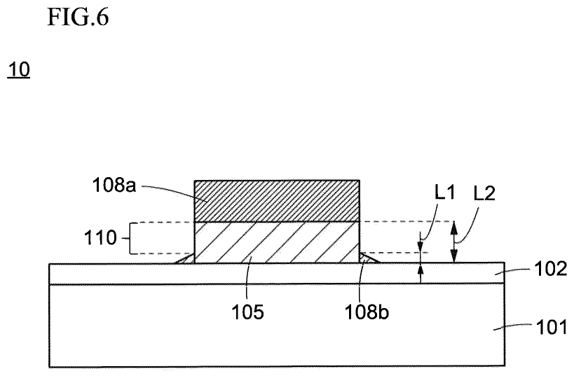

Next, the resist mask 107 is removed as shown in FIG. 6. Dry type resist stripping or wet type resist stripping can be used to remove the resist mask 107.

Through the above process, the multilayered structure 10 shown in FIG. 6 is obtained. The semiconductor layer 108a of the multilayered structure 10 in the present embodiment is patterned from the first portion 106a of the semiconductor film 106 containing gallium nitride, and therefore has crystallinity oriented along a specific orientation axis, reflecting the orientation of the orientation layer 105. The side protection portion 108b containing gallium nitride, which is arranged on the side surface of the alignment layer 105, can protect the semiconductor layer 108a and the alignment layer 105 from the etching used to form the semiconductor layer 108a. Thus, damage due to etching of the side surface of the semiconductor layer 108a and the alignment layer 105 can be suppressed. Therefore, a semiconductor device with excellent characteristics can be realized by processing the multilayered structure 10 having the semiconductor layer 108a of the present embodiment and using it in the semiconductor device.

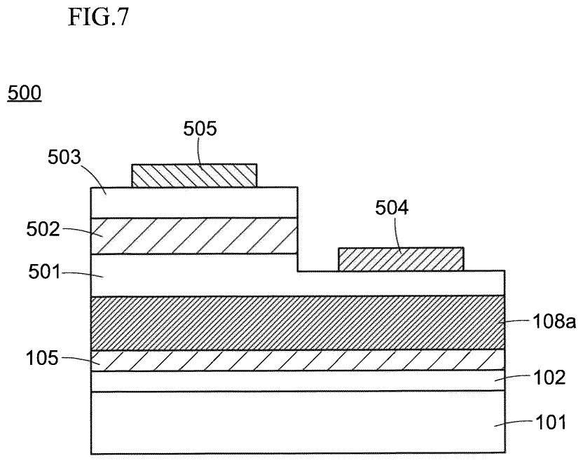

FIG. 7 is an end view of a semiconductor device 500 having the multilayered structure 10 in the first embodiment. Specifically, the semiconductor device 500 shown in FIG. 7 is an example of an LED device manufactured utilizing the multilayered structure 10 shown in FIG. 6. In FIGS. 6 and 7, the relationship between the thicknesses of the orientation layer 105 and the semiconductor layer 108a is different, but for the sake of explanation, the thickness of the orientation layer 105 is only exaggerated in FIG. 6.

Once the semiconductor layer 108a is formed as shown in FIG. 6, an n-type gallium nitride layer 501, a light-emitting layer 502, and a p-type gallium nitride layer 503 are successively grown on top of the semiconductor layer 108a. Thereafter, parts of the n-type gallium nitride layer 501, the light-emitting layer 502, and the p-type gallium nitride layer 503 are removed so that the n-type gallium nitride layer 501 is exposed. Finally, the n-type electrode 504 and the p-type electrode 505 are formed in contact with the n-type gallium nitride layer 501 and the p-type gallium nitride layer 503, respectively.

Through the above process, the semiconductor device 500 shown in FIG. 7 is completed. The semiconductor device 500 in the present embodiment is formed using the semiconductor layer 108a, which uses only the first portion 106a with high crystallinity out of the semiconductor film 106 containing gallium nitride formed on the amorphous substrate 101. Therefore, according to the present embodiment, the semiconductor device 500 can be manufactured on the inexpensive amorphous substrate 101. In addition, according to the present embodiment, since the semiconductor film 106 containing gallium nitride with high crystallinity can be formed by the sputtering method, the semiconductor device 500 can be manufactured with high throughput without being exposed to a high temperature throughout the entire process.

The semiconductor device 500 shown in FIG. 7 is merely an example of an LED element and may be an LED element of another structure. For example, the light-emitting layer 502 may have a quantum-well structure in which the gallium nitride layer and the indium gallium nitride layer are alternately stacked.

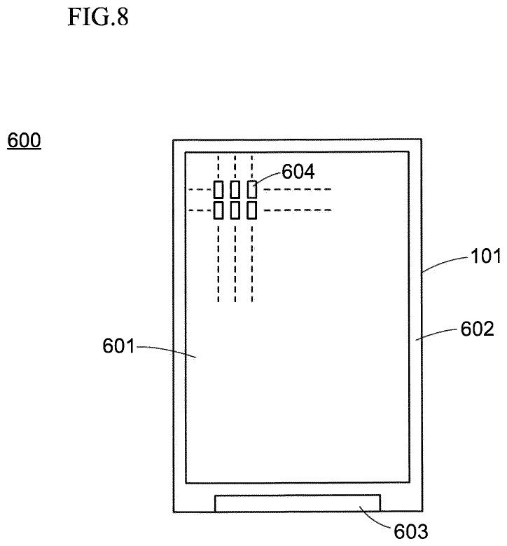

FIG. 8 is a plan view showing a light-emitting device 600 using the semiconductor device 500 including the multilayered structure 10 according to the first embodiment. As shown in FIG. 8, a display unit 601 and a peripheral circuitry 602 are arranged on the amorphous substrate 101. A terminal 603 for inputting various signals (video signals and control signals) to the light-emitting device 600 is arranged in part of the peripheral circuitry 602. A plurality of pixels 604 is arranged in a matrix inside the display unit 601.

In the following description, a variation of the multilayered structure 10 of the present embodiment will be described. In the figures, the same elements as those of the first embodiment will be marked with the same symbols and duplicate explanations will be omitted.

### <Variation>

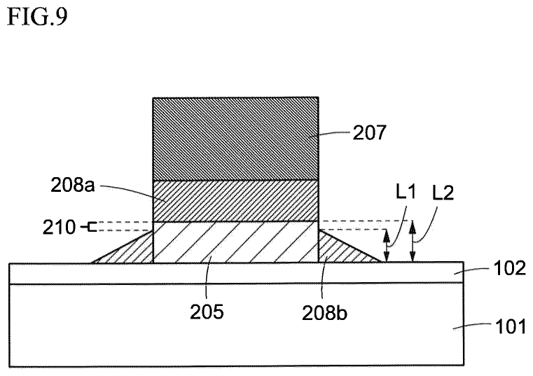

FIG. 9 is an end view of a multilayered structure 20 of an embodiment of the present invention. First, the state shown in FIG. 4 can be obtained according to the process described using FIG. 1 through FIG. 4 of the first embodiment.

Next, as shown in FIG. 9, gallium nitride is etched into the semiconductor film (the semiconductor film 106 containing gallium nitride shown in FIG. 4) using a resist mask 207 to form a semiconductor layer 208a having a pattern and a side protection portion 208b.

As explained in FIG. 5, the formation of the side protection portion 208b can be performed by etching the semiconductor film 106 shown in FIG. 5 until the side surface of the orientation layer 105 is partially exposed from the semiconductor film 106, or until the top of the orientation layer 205, shown in FIG. 9, is exposed.

If the crystallinity of the side protection portion 208b is sufficiently low and the electrical insulation of the side protection portion 208b is high, a film thickness L1 of the side protection portion 208b may be thinner than a film thickness L2 of the orientation layer 205 and may be more than half of the film thickness L2.

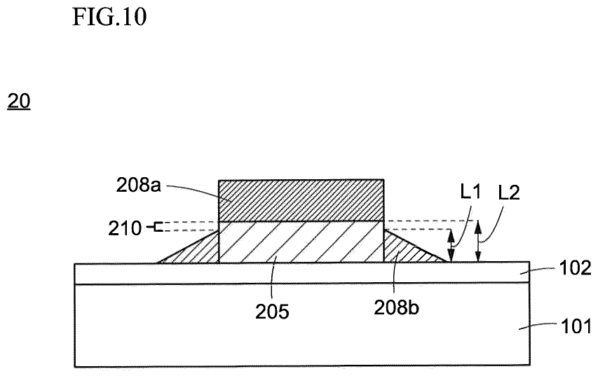

Next, the resist mask 207 is removed as shown in FIG. 6, and the multilayered structure 20 shown in FIG. 10 is obtained. The semiconductor layer 208a of the multilayered structure 20 in the present embodiment is patterned from the first portion 106a of the semiconductor film 106 containing gallium nitride, and thus has crystallinity oriented along a specific orientation axis reflecting the orientation of the orientation layer 205. Furthermore, the side protection portion 208b is provided to cover more of the side surface of the alignment layer 205. Accordingly, the semiconductor layer 208a and the orientation layer 205 can be protected from etching used in forming the semiconductor layer 208a, and the damage caused by etching of the side surfaces of the semiconductor layer 208a and the orientation layer 205 can be further suppressed. Therefore, a semiconductor device with excellent characteristics can be realized by processing the multilayered structure 20 having the semiconductor layer 208a of the present embodiment and using it in the semiconductor device.

### Second Embodiment

In the present embodiment, an example in which a semiconductor device is formed having a structure different from that of the first embodiment will be described. Specifically, in the present embodiment, an example in which a HEMT (High Electron Mobility Transistor) is formed as a semiconductor device will be described. In the drawing, the same elements as those shown in the first embodiment are denoted by the same reference signs, and redundant explanations are omitted.

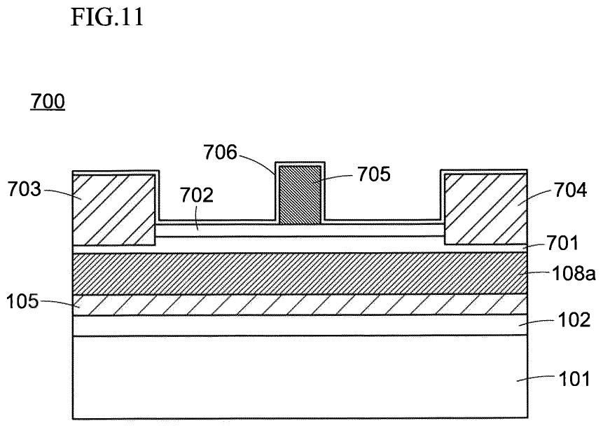

FIG. 11 is an end view showing a semiconductor device 700 including a gallium nitride-based semiconductor layer according to the second embodiment. Specifically, the semiconductor device 700 shown in FIG. 11 is an example of the HEMT manufactured using the semiconductor pattern 111 shown in FIG. 6 in the first embodiment. In FIGS. 6 and 11, the relationship between the thicknesses of the orientation layer 105 and the semiconductor layer 108 is different, but for the sake of explanation, the thickness of the orientation layer 105 is only exaggerated in FIG. 6.

An n-type aluminum gallium nitride layer 701 and an n-type aluminum gallium nitride layer 702 are successively formed on top of the semiconductor layer 108, which consists of a gallium nitride layer. The sputtering method can be used to form these gallium nitride-based semiconductor layers. A trench reaching the n-type aluminum gallium nitride layer 701 is arranged in the n-type aluminum gallium nitride layer 701 and the n-type aluminum gallium nitride layer 702, and a source electrode 703 and a drain electrode 704 are arranged therein. A gate electrode 705 in contact with the n-type aluminum gallium nitride layer 702 is arranged between the source electrode 703 and the drain electrode 704. Finally, a silicon nitride layer 706 is formed as a protective layer, thereby completing the HEMT shown in FIG. 11.

The semiconductor device 700 of the present embodiment is formed using the highly crystalline gallium nitride layer (the semiconductor layer 108) formed on the amorphous substrate 101. Therefore, according to the present embodiment, the semiconductor device 700 can be manufactured on the inexpensive amorphous substrate 101. In addition, according to the present embodiment, since a plurality of gallium nitride-based semiconductor layers is formed by a sputtering method, the semiconductor device 700 can be manufactured with high throughput without being exposed to high temperature throughout the entire process. In addition, the semiconductor device 700 shown in FIG. 11 is merely an example of the HEMT, and may be the HEMT of another structure.

Each of the embodiments described above as an embodiment of the present invention can be appropriately combined and implemented as long as no contradiction is caused. The addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A multilayered structure comprising:
an amorphous substrate having an insulating surface;
an orientation layer having a pattern on the amorphous substrate having the insulating surface;
a semiconductor layer containing gallium nitride having a pattern arranged on the orientation layer; and
a side protection portion containing gallium nitride arranged on a side surface of the orientation layer,
wherein the semiconductor layer and the side protection portion are separated at the side surface of the orientation layer.

2. A multilayered structure comprising:
an amorphous substrate having an insulating surface;
an orientation layer having a pattern on the amorphous substrate having the insulating surface;
a semiconductor layer containing gallium nitride having a pattern arranged on a top surface of the orientation layer; and
a side protection portion containing gallium nitride arranged on a side surface of the orientation layer,
wherein
the orientation layer contains an exposed portion not covered by the semiconductor layer and the side protection portion, and
the exposed portion is arranged between the semiconductor layer and the side protection portion.

3. The multilayered structure according to claim 1,
wherein an angle between a bottom surface and the side surface of the orientation layer is greater than 60° and less than 90°.

4. The multilayered structure according to claim 2,
wherein an angle between a bottom surface and the side surface of the orientation layer is greater than 60° and less than 90°.

5. The multilayered structure according to claim 1,
wherein
the semiconductor layer has gallium nitride of the same composition as the side protection portion, and
crystallinity of gallium nitride in the semiconductor layer is higher than crystallinity of gallium nitride in the side protection portion.

6. The multilayered structure according to claim 2,
wherein
the semiconductor layer has gallium nitride of the same composition as the side protection portion, and
crystallinity of gallium nitride in the semiconductor layer is higher than crystallinity of gallium nitride in the side protection portion.

7. The multilayered structure according to claim 1,
wherein
the semiconductor layer has gallium nitride of the same composition as the side protection portion, and
electrical insulation of the side protection portion is higher than electrical insulation of the semiconductor layer.

8. The multilayered structure according to claim 2,
wherein
the semiconductor layer has gallium nitride of the same composition as the side protection portion, and
electrical insulation of the side protection portion is higher than electrical insulation of the semiconductor layer.

9. The multilayered structure according to claim 1,
wherein the side protection portion is also arranged on the insulating surface.

10. The multilayered structure according to claim 2,
wherein the exposed portion separates the semiconductor layer from the side protection portion.

11. The multilayered structure according to claim 2,
wherein the side protection portion is also arranged on the insulating surface.

12. A semiconductor device comprising:
the multilayered structure according to claim 1.

13. A semiconductor device comprising:
the multilayered structure according to claim 2.

14. A manufacturing method of a multilayered structure comprising:
forming an orientation layer having a pattern on an amorphous substrate having an insulating surface;
forming a semiconductor film containing gallium nitride to cover the orientation layer; and
forming a semiconductor layer containing gallium nitride having a pattern on a top surface of the orientation layer by etching the semiconductor film, as well as forming a side protection portion containing gallium nitride arranged on a side surface of the orientation layer,
wherein the semiconductor layer and the side protection portion are separated from each other.

15. The manufacturing method of the multilayered structure according to claim 14, wherein
an angle between a bottom surface and a side surface of the orientation layer is equal to or greater than 60° and less than or equal to 90°.

16. The manufacturing method of the multilayered structure according to claim 14,
wherein the formation of the orientation layer further comprises:
depositing an orientation film on the amorphous substrate having the insulating surface; and
forming the orientation layer by etching the orientation film.

17. The manufacturing method of the multilayered structure according to claim 14, further comprising,
etching the semiconductor film to form a semiconductor layer containing gallium nitride having a pattern on a top surface of the orientation layer and a side protection portion containing gallium nitride on a side surface of the orientation layer,
wherein the portion of the orientation layer exposed from the semiconductor film is located between the semiconductor layer and the side protection portion.
